(19) United States
(12) Patent Application Publication
(10) Pub. No.: US 2012/0280330 A1
(43) Pub. Date: Nov. 8, 2012

(54) SEMICONDUCTOR DEVICES AND METHODS FOR FABRICATING THE SAME

(75) Inventors: Hye-Lan Lee, Hwaseong-si (KR); Hong-Bae Park, Seoul (KR); Sang-Jin Hyun, Suwon-si (KR); Sang-Bom Kang, Seoul (KR); Jae-Jung Kim, Suwon-si (KR)

(73) Assignee: SAMSUNG ELECTRONICS CO., LTD., Suwon-si (KR)

(21) Appl. No.: 13/422,106

(22) Filed: Mar. 16, 2012

(30) Foreign Application Priority Data
May 6, 2011 (KR) 10-2011-0043039

(51) Int. Cl. H01L 27/088

(52) U.S. Cl. 257/392; 257/E27.06

(57) ABSTRACT

Semiconductor devices including first and second fin active regions protruding vertically from a substrate and integrally formed with the substrate, a gate insulation layer formed on the first and second fin active regions, a first gate metal contacting the gate insulation layer on the first fin active region, and a second gate metal contacting the first gate metal on the first fin active region and contacting the gate insulation layer on the second fin active region.

### CROSS-REFERENCE TO RELATED APPLICATION

This application claims priority to Korean Patent Application No. 10-2011-0043039 filed on May 6, 2011 in the Korean Intellectual Property Office, and all the benefits accruing therefrom under 35 U.S.C. §119, the contents of which in its entirety are herein incorporated by reference.

### BACKGROUND

1. Field

Example embodiments relate to semiconductor devices and methods of fabricating the same

2. Description of the Related Art

Semiconductor memory devices having low power and high speed characteristics, and manufacturing processes of such semiconductor memory devices, are increasingly advancing toward improvement of integration density. In order to achieve high speed operation of a field effect transistor (FET) used as a semiconductor device, a channel length of the FET should be reduced. However, in a planer type FET, a reduction in channel length may increase the effect of an electric field due to a drain voltage and deteriorate channel driving capability, resulting in a short channel effect.

In addition, in a case where a channel concentration is increased in an effect to adjust a threshold voltage of the FET, carrier mobility and current driving capability may decrease and source/drain junction leakage current may increase. A fin FET that employs a three-dimensional structure may overcome the limitations of the planar type FET.

### SUMMARY

Example embodiments may provide semiconductor devices with different threshold voltages. Example embodiments may provide methods of fabricating semiconductor devices with different threshold voltages.

According to at least one example embodiment, there is provided a semiconductor device including first and second fin active regions protruding vertically from a substrate and integrally formed with the substrate, a gate insulation layer formed on the first and second fin active regions, a first gate metal contacting the gate insulation layer on the first fin active region, and a second gate metal contacting the first gate metal on the first fin active region and contacting the gate insulation layer on the second fin active region.

According to at least one other example embodiment, there is provided a semiconductor device including first and second fin active regions protruding in a first direction perpendicular to a substrate and integrally formed with the substrate and extending in a second direction perpendicular to the first direction, a gate insulation layer formed on the first and second fin active regions, and first and second gate metals formed on the gate insulation layer to cross the first and second fin active regions and extending in a third direction perpendicular to the first and second directions. The first and second gate metals are sequentially stacked on the first fin active region and sidewalls of the first and second gate metals are aligned in the third direction, and the second gate metal contacting the gate insulation layer is formed on the second fin active region.

According to at least one example embodiment, a semiconductor device includes first and second fin active regions, a gate insulation layer on the first and second fin active regions, a first gate metal contacting the gate insulation layer on the first fin active region, and a second gate metal on the first gate metal on the first fin active region and contacting the gate insulation layer on the second fin active region.

According to at least one example embodiment, a semiconductor device includes first and second fin active regions protruding in a first direction perpendicular to a substrate and integral with the substrate, the first and second fin active regions extending in a second direction perpendicular to the first direction, a gate insulation layer on the first and second fin active regions, and first and second gate metals on the gate insulation layer and crossing the first and second fin active regions, the first and second gate metals extending in a third direction perpendicular to the first and second directions, the first and second gate metals sequentially stacked on the first fin active region, sidewalls of the first and second gate metals being aligned in the third direction, the second gate metal being in contact with the gate insulation layer on the second fin active region.

According to at least one example embodiment, a semiconductor device includes a first fin field effect transistor (FIN-FET) with a first gate stack including first and second metal layers, and a second FIN-FET with a second gate stack including the second metal layer, the second gate stack not including the first metal layer.

### BRIEF DESCRIPTION OF THE DRAWINGS

Example embodiments will be more clearly understood from the following brief description taken in conjunction with the accompanying drawings. FIGS. 1-18 represent non-limiting, example embodiments as described herein.

FIG. 1 is a perspective diagram illustrating semiconductor devices according to at least one example embodiment;

FIG. 2 is a cross-sectional view taken along the line 2-2′ of FIG. 1;

FIG. 3 is a perspective diagram illustrating semiconductor devices according to at least one other example embodiment;

FIG. 4 is a cross-sectional view taken along the line 4-4′ of FIG. 3;

FIG. 5 is a perspective diagram illustrating semiconductor devices according to a modified example embodiment of FIG. 4;

FIG. 6 is a cross-sectional view taken along the line 6-6′ of FIG. 5;

FIGS. 7-15 are perspective diagrams illustrating methods of fabricating semiconductor devices according to at least one example embodiment; and

FIGS. 16-18 illustrate results of experimental example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully hereinafter with reference to the accompanying drawings, in which example embodiments of the invention are shown. Example embodiments may, however, be embodied in many different forms and should not be construed as being limited to the embodiments set forth herein; rather, these embodiments are provided so that this disclosure will be thorough and complete, and will filly convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

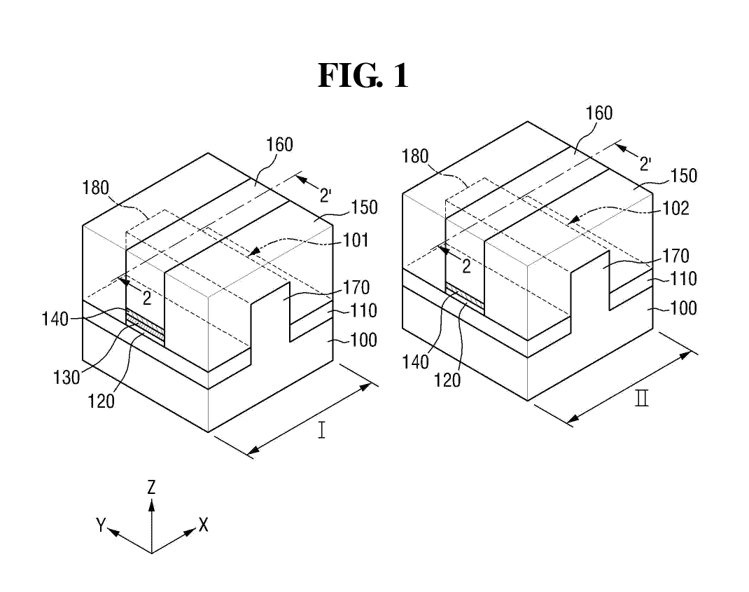

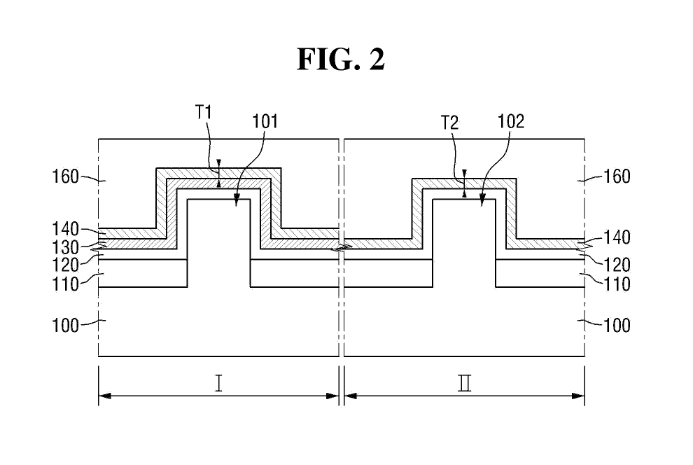

FIG. 1 is a perspective diagram illustrating semiconductor devices according to at least one example embodiment. FIG. 2 is a cross-sectional view taken along the line 2-2′ of FIG. 1. Referring to FIGS. 1 and 2, a semiconductor device according to an example embodiment may include first and second fin active regions 101 and 102, a gate insulation layer 120, and first and second metal gates 130 and 140. The first and second fin active regions 101 and 102 may protrude in a perpendicular direction from a substrate 100, and may be integral with the substrate 100. The first fin active region 101 may be in a first region I of the substrate 100 and may protrude from the substrate 100 in a first direction (e.g., in the Z direction) perpendicular to the substrate 100 so as to be integral with the substrate 100. The second fin active region 102 may be in a second region II of the substrate 100 and may protrude from the substrate 100 in the first direction (e.g., in the Z direction) perpendicular to the substrate 100 so as to be integral with the substrate 100.

According to at least one example embodiment, the first and second fin active regions 101 and 102 may extend in a second direction (e.g., in the Y direction) perpendicular to the first direction (e.g., in the Z direction). A source region 170 may be at one side of the first and second fin active regions 101 and 102, and a drain region 180 may be at a different side thereof. An isolation layer 110 for isolating devices may be at either side of the first and second fin active regions 101 and 102. The gate insulation layer 120 may be on the first and second fin active regions 101 and 102. A gate insulation layer 120 may be on and conform to, or conformally surround, at least a portion of the first and second fin active regions 101 and 102. The gate insulation layer 120 may extend in a third direction (e.g., in the X direction) to cross the first and second fin active regions 101 and 102. According to some example embodiments, sidewalls of the gate insulation layer 120 may be aligned with sidewalls of the first gate metal 130 or the second gate metal 140 in the third direction (e.g., in the X direction).

The gate insulation layer 120 may be a high dielectric constant (high-k) layer made of a high-k material. Specific examples of high-k materials may include hafnium (Hf) and/or zirconium (Zr) based metal-oxide, metal-oxide-nitride, and/or titanium (Ti), tantalum (Ta), aluminum (Al) and/or lanthanide (La) doped materials thereof, but may not be limited thereto. The first and second gate metals 130 and 140 may be on the gate insulation layer 120. The first and second gate metals 130 and 140 may be sequentially stacked on the first fin active region 101 in a stacked structure and may contact the gate insulation layer 120. The second gate metal 140 may be on the second fin active region 102 contacting the gate insulation layer 120. The first gate metal 130 may not be on the second fin active region 102.

The first and second gate metals 130 and 140 may be on the gate insulation layer 120 while crossing the first and second fin active regions 101 and 102 and extending in the third direction (e.g., in the X direction). The first and second gate metal 130 and 140 may be sequentially stacked in a stacked structure on the first fin active region 101 contacting the gate insulation layer 120 and extending in the third direction (e.g., in the X direction). The second gate metal 140 may be on the second fin active region 102 contacting the gate insulation layer 120 and extending in the third direction (e.g., in the X direction). The sidewalls of the stacked structure of the first and second gate metals 130 and 140 on the first fin active region 101 may be aligned in the third direction (e.g., in the X direction).

Each of the first gate metal 130 and the second gate metal 140 may include, for example, at least one of a first metal-carbide, a first metal-second metal-carbide, a first metal-second metal, a first metal-second metal-nitride, a first metal-nitride, a first metal-silicide, and a first metal-silicon-nitride. For example, the second metal may be aluminum (Al), but may not be limited thereto. A thickness T1 of the second gate metal 140 on the first fin active region 101 and a thickness T2 of the second gate metal 140 on the second fin active region 102 may be the same with each other. The thickness T1 may equal the thickness T2.

The first gate metal 130 and the second gate metal 140 may include different materials. For example, while the first gate metal 130 may include a first metal-nitride, the second gate metal 140 may include a first metal-second metal-carbide. In this case, the first and second gate metals 130 and 140 in the stacked structure may be formed on the first fin active region 101 and the second gate metal 140 may be formed on the second fin active region 102 may be of different work functions. The work function difference may be presumably caused due to existence of a barrier metal. While the first gate metal 130 may serve as a barrier metal for preventing a metallic material from being diffused in a case of the second gate metal 140 on the first fin active region 101, no barrier metal may be included in a case that the second gate metal 140 is on the second fin active region 102.

The work function difference between the first and second gate metals 130 and 140 with the stacked structure that may be on the first fin active region 101 and the second gate metal 140 may be on the second fin active region 102 may also be changed by changing a material included in the first gate metal 130. The work function difference between the stacked structure of the first and second gate metals 130 and 140 and the second gate metal 140 may be achieved by changing the material included in the first gate metal 130 from, for example, a first metal-nitride to a first metal-silicide and/or a first metal-silicon-nitride. This is presumably because there is a difference in the barrier metal function of the first gate metal 130 as the material that may be the first gate metal 130 may be changed.

According to some other example embodiments, the materials that may be included in the first gate metal 130 and the second gate metal 140 may be the same with each other but the composition ratios thereof may be different from each other. According to at least one example embodiment, both of the first and second gate metals 130 and 140 may include a first metal-second metal-carbide, but a second metal to first metal ratio of the second gate metal 140 may be higher than that of the first gate metal 130. In this case, a difference in the second metal to first metal ratio may bring about a difference in the work function between the first gate metal 130 and the second gate metal 140 and a difference in the work function between the stacked structure of the first and second gate metals 130 and 140 on the first fin active region 101 and the second gate metal 140 on the second fin active region 102. In a case where no other parameters are changed except for the second metal to first metal ratio, a difference in work function is brought about.

According to some other example embodiments, composition ratios and component materials of the first gate metal 130 and the second gate metal 140 may be completely the same with each other, and the overall thickness of the stacked structure of the first and second gate metals 130 and 140 on the first fin active region 101 may be greater than a thickness of the second gate metal 140 that may be formed on the second fin active region 102. The gate metals with the same material and the same composition may be formed to different thicknesses. In this case, the first and second gate metals 130 and 140 with the stacked structure on the first fin active region 101 and the second gate metal 140 on the second fin active region 102 may be of different work functions. This may be presumably attributable to a change in the relative arrangement and/or composition ratio of component materials, which may be caused by a change in the thickness of the gate metal.

If the work functions of the first and second gate metals 130 and 140 of a stacked structure on the first fin active region 101 are different from the work function of the second gate metal 140 on the second fin active region 102, a threshold voltage Vth of a first transistor of the first fin active region 101, that may include the first and second gate metals 130 and 140, the source region 170, and the drain region 180 may be different from a threshold voltage of a second transistor that may include the second fin active region 102, the second gate metal 140, the source region 170, and the drain region 180. A transistor with various threshold voltages may be achieved by varying materials, composition ratios, thicknesses of the first and second gate metals 130 and 140 (e.g., a fin FET). According to at least one example embodiment, a difference in the threshold voltage between the first transistor and the second transistor may be in a range of, for example, 200 to 300 mV, but may not be limited thereto, and multiple threshold voltages may be implemented in various manners according to the necessity.

According to some other example embodiments, the first insulation layer 150 may be on the first and second fin active regions 101 and 102 and contacting the first and second fin active regions 101 and 102, and the second insulation layer 160 may be on a second gate metal 140 and contacting the second gate metal 140. The first insulation layer 150 and the second insulation layer 160 may be separately formed because the first and second gate metals 130 and 140 may be formed after forming the source region 170 and the drain region 180.

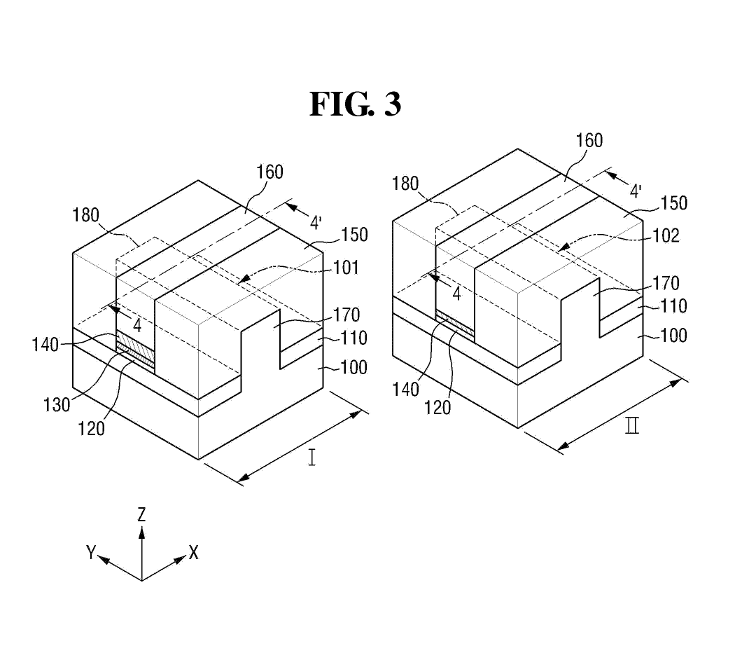

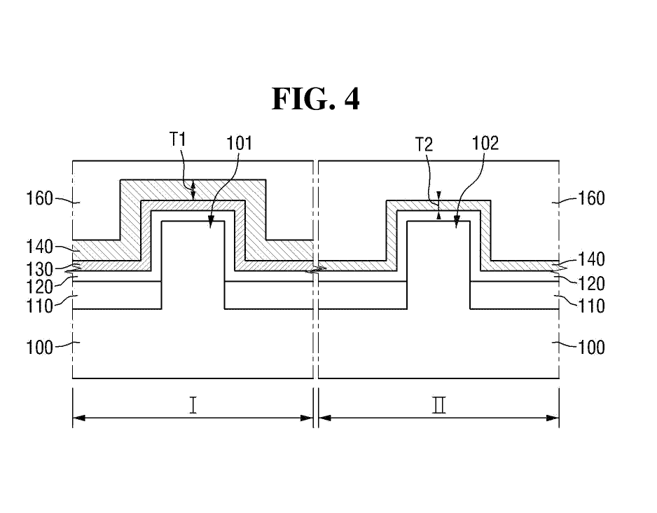

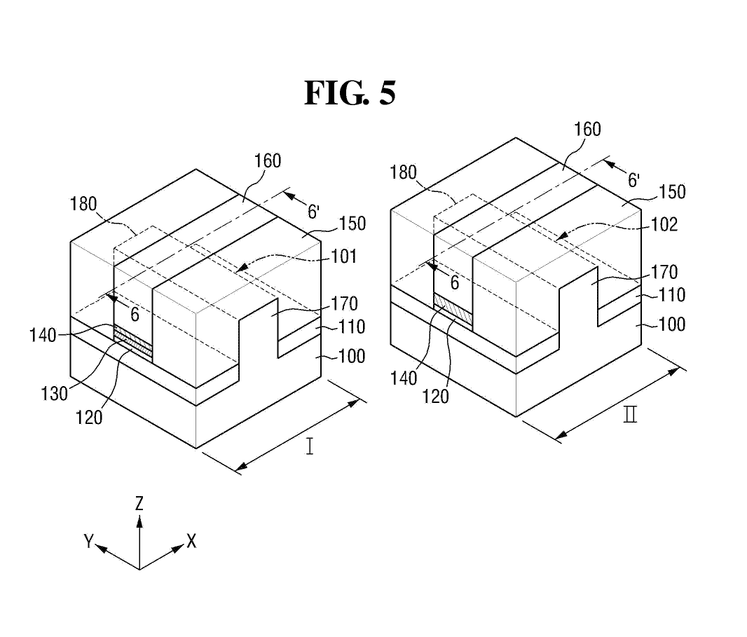

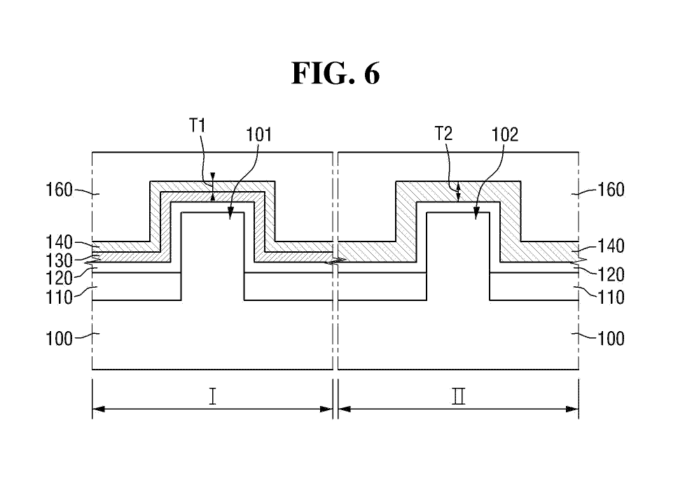

FIG. 3 is a perspective diagram illustrating semiconductor devices according to at least one other example embodiment. FIG. 4 is a cross-sectional view taken along the line 4-4′ of FIG. 3. FIG. 5 is a perspective diagram illustrating semiconductor devices according to a modified example embodiment of FIG. 4. FIG. 6 is a cross-sectional view taken along the line 6-6′ of FIG. 5. Features of example embodiments that are previously described may not be repeated for clarity of description. The same numerals indicate the same elements.

Referring to FIGS. 3 and 4, according to other example embodiments, a thickness T1 of a second gate metal 140 that may be on a first fin active region 101 may be greater than a thickness T2 of a second gate metal 140 that may be on a second fin active region 102. An increased difference in the work function between the first and second gate metal 130 and 140 of a stacked structure that may be on the first fin active region 101 and the second gate metal 140 that may be on the second fin active region 102, may be achieved. The thickness T1 of the second gate metal 140 that may be on the first fin active region 101 may be made greater than the thickness T2 of the second gate metal 140 that may be on a second fin active region 102, thereby achieving an increased work function difference depending on the thickness of a gate metal.

Referring to FIGS. 5 and 6, according to a modified example embodiment of FIG. 4, a thickness T1 of a second gate metal 140 that may be on the first fin active region 101 may be less than a thickness T2 of a second gate metal 140 that may be on the second fin active region 102. An increased difference in the work function between the first and second gate metal 130 and 140 of a stacked structure that may be on the first fin active region 101 and the second gate metal 140 that may be on the second fin active region 102, may be achieved.

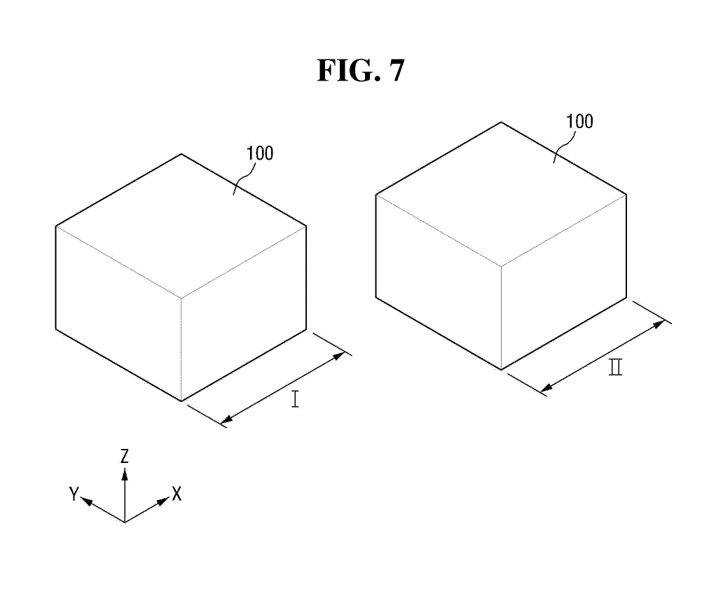

FIGS. 7-15 are perspective diagrams illustrating methods of fabricating semiconductor devices according to at least one example embodiment. Referring to FIGS. 7-12, a substrate may be provided. The substrate may include first and second fin active regions that may protrude vertically from the substrate and may be integrally formed with the substrate, and a gate insulation layer formed on the first and second fin active regions. In the following description, fabricating methods for providing a substrate will be described by way of example, but example embodiments are not limited thereto.

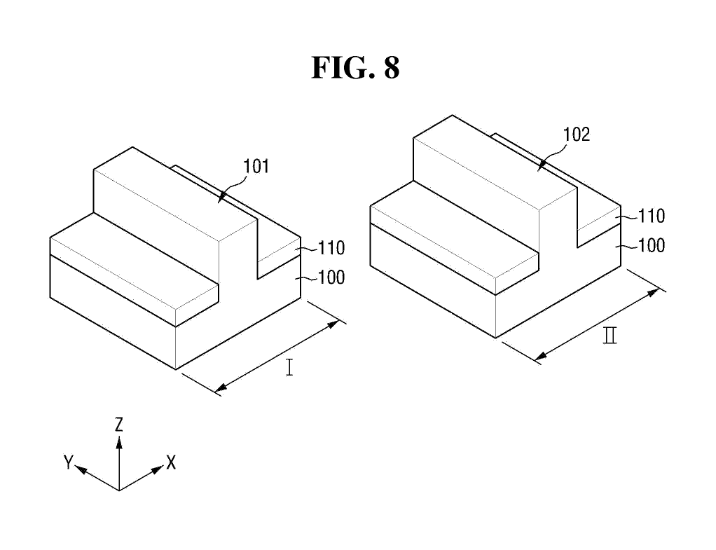

Referring to FIG. 7, a substrate 100 including a first region I and a second region II may be prepared. Referring to FIG. 8, a region may be etched to form first and second fin active regions 101 and 102, and an isolation region (not shown) on the first region I and the second region II of the substrate 100. The first and second fin active regions 101 and 102 may protrude in a first direction (e.g., in the Z direction) perpendicular to the substrate 100 and may be integrally formed with the substrate 100. An isolation layer 110 may be formed on the isolation region. The first and second fin active regions 101 and 102 may be formed to extend in a second direction (e.g., in the Y direction).

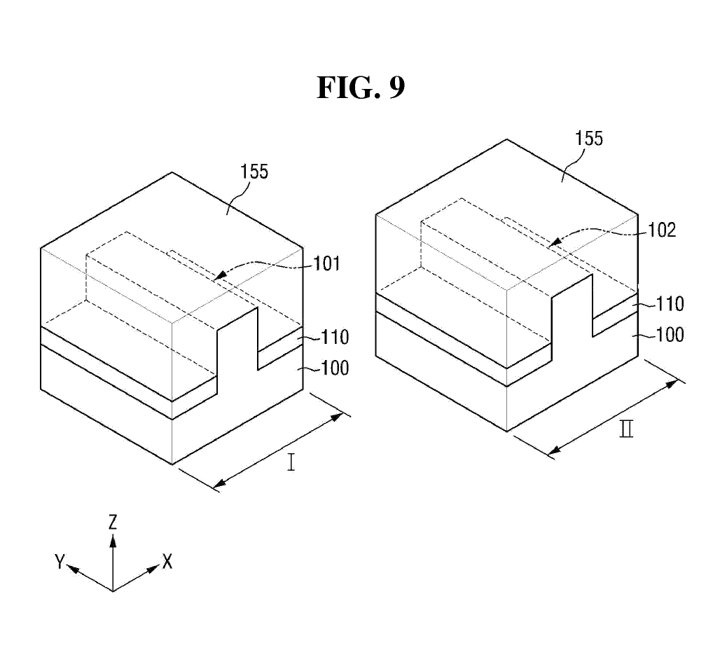

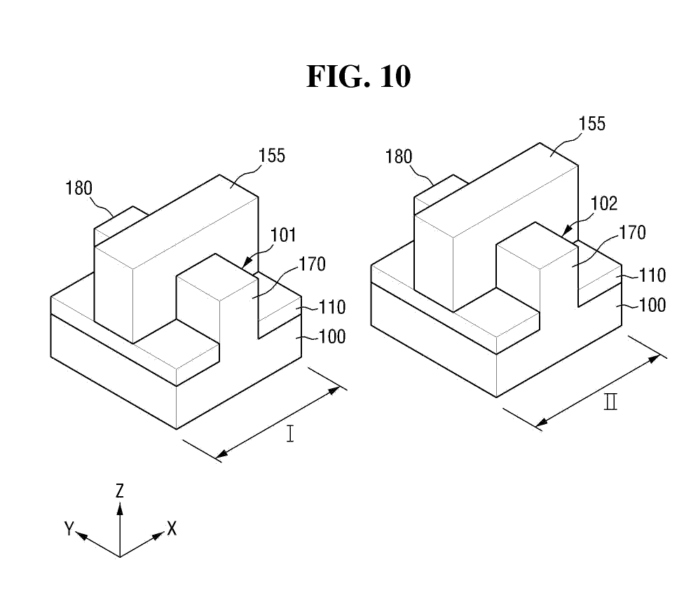

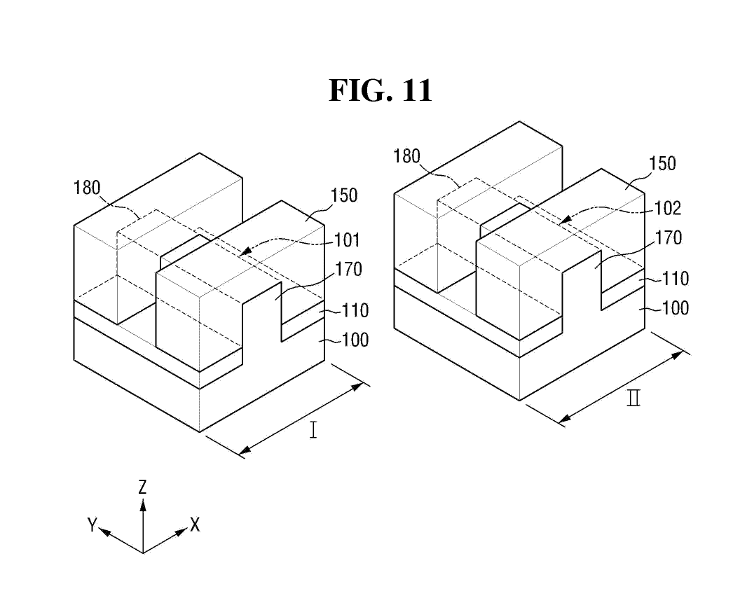

Referring to FIG. 9, a dummy gate layer 155 may be formed on the first and second fin active regions 101 and 102 and the isolation layer 110. Referring to FIG. 10, the dummy gate layer 155 on one side of the first and second fin active regions 101 and 102 where a source region 170 may be formed, and on the other side of the first and second fin active regions 101 and 102 where a drain region 180 may be formed, may be removed. Impurities may be injected into the first and second fin active regions 101 and 102 by, for example, doping and/or implanting, to form the source region 170 and the drain region 180. The dummy gate layer 155 may function as a mask layer that may prevent injection of impurities. The first and second fin active regions 101 and 102 may both be n-type, both be p-type or may each be a different conductivity type. Referring to FIG. 11, a first insulation layer 150 may be formed on the first and second fin active regions 101 and 102 that may include the source region 170 and the drain region 180, and the remainder of the dummy gate layer (155 of FIG. 10) may be removed. Portions of the first and second fin active regions 101 and 102, where a gate metal may be formed, may be exposed.

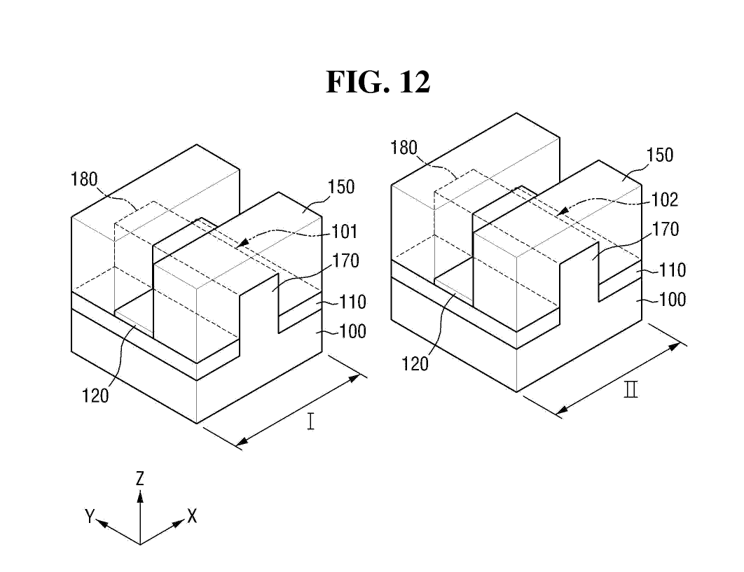

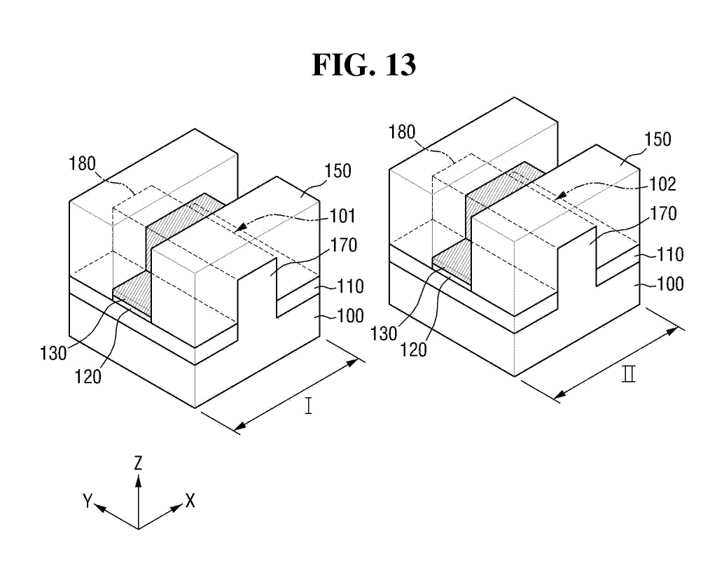

Referring to FIG. 12, a gate insulation layer 120 may be formed on the exposed first and second fin active regions 101 and 102. The gate insulation layer 120 may be formed on the exposed first and second fin active regions 101 and 102 so as to extend in a third direction (e.g., in the X direction) to cross the first and second fin active regions 101 and 102. Referring to FIG. 13, a first gate metal 130 that may contact the gate insulation layer 120 may be formed on the first and second fin active regions 101 and 102. The first gate metal 130 may be formed on the first and second fin active regions 101 and 102 so as to cross the first and second fin active regions 101 and 102 and extend in the third direction (e.g., in the X direction).

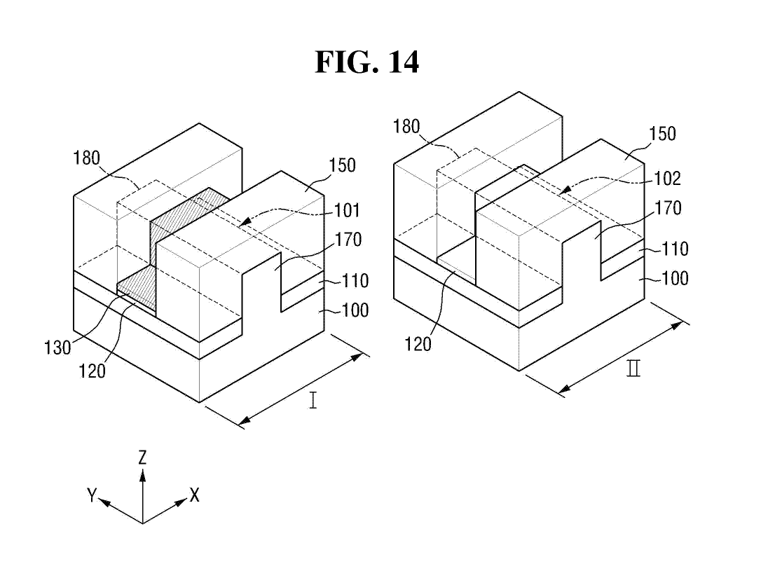

Referring to FIG. 14, the first gate metal 130 formed on the second fin active region 102 may be removed. The selective removal of the first gate metal 130 may be performed by, for example, etching using a mask layer (not shown) formed on the first gate metal 130 in the first region I of the substrate 100 while no mask layer is formed on the first gate metal 130 in the second region II of the substrate 100. However, the selective removal according to example embodiments is described only for purposes of illustration, and any well known method may be used as long as the method allows the first gate metal 130 formed on the second fin active region 102 to be selectively removed.

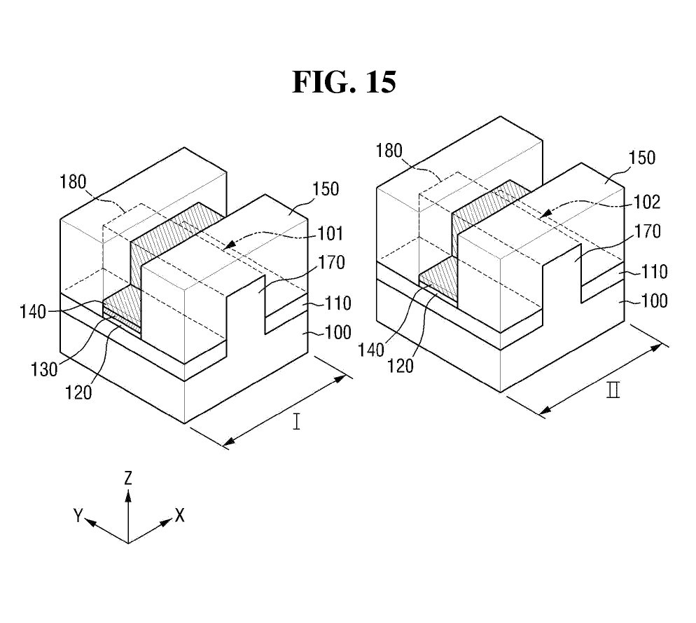

Referring to FIG. 15, a second gate metal 140 may be formed on the first gate metal 130 that is formed on the first fin active region 101 and on the gate insulation layer 120 that is formed on the second fin active region 102. A thickness of the second gate metal 140 on the first gate metal 130 in the first region I of the substrate 100 and a thickness of the second gate metal 140 on the gate insulation layer 120 in the second region II of the substrate 100 may be equal to or different from each other according to necessity. Work functions of the first and second gate metals 130 and 140, and threshold voltages of a transistor may be adjusted in various manners, which may be the same as described above and repeated descriptions thereof may be omitted. A second insulation layer (160 of FIGS. 1, 3 and 5) may be formed on the second gate metal 140.

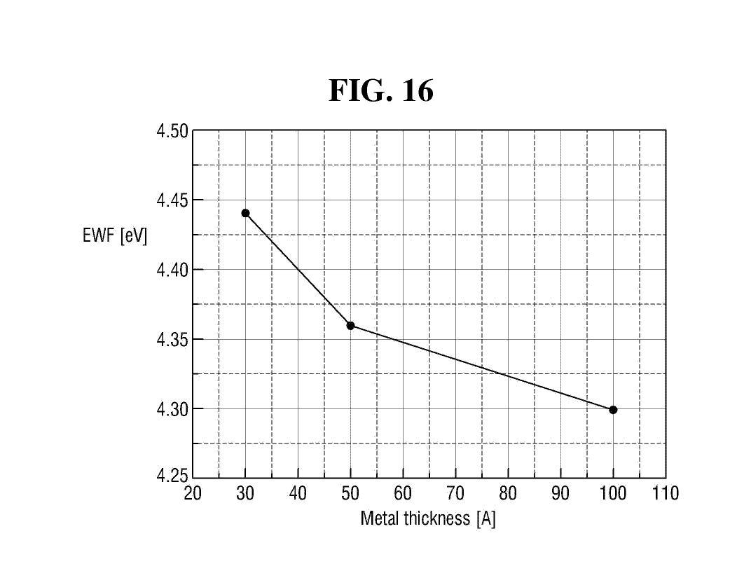

Example embodiments will be additionally described through the following examples. FIGS. 16-18 illustrate results of experimental example embodiments.

### Experimental Example 1

A gate metal including metal (M)-aluminum (Al)-carbide is prepared, and work functions of the gate metal measured while varying thicknesses of the gate metal from about 30 Å to 100 Å. The measurement result is illustrated in FIG. 16. Referring to FIG. 16, it may be understood that the work function of the gate metal is reduced as the thickness of the gate metal increases. This may be attributable to a change in the relative arrangement or ratio of metal (M), aluminum (Al) and carbide in the gate metal, which is caused by the increased thickness of the gate metal.

### Experimental Example 2

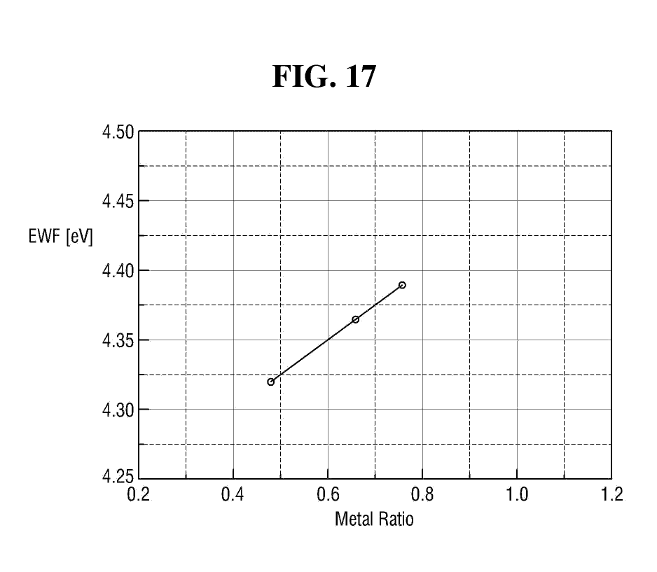

A gate metal including metal (M)-aluminum (Al)-carbide is prepared, and work functions of the gate metal measured while varying a composition ratio of aluminum (Al) to metal (M). The measurement result is illustrated in FIG. 17. Referring to FIG. 17, it may be understood that the greater the composition ratio of aluminum (Al) to metal (M), that is, the larger the specific weight of aluminum (Al) in the gate metal, the larger the work function of the gate metal. Therefore, it may be understood that the work function of the gate metal may vary according to the composition ratio of components materials of the gate metal.

### Experimental Example 3

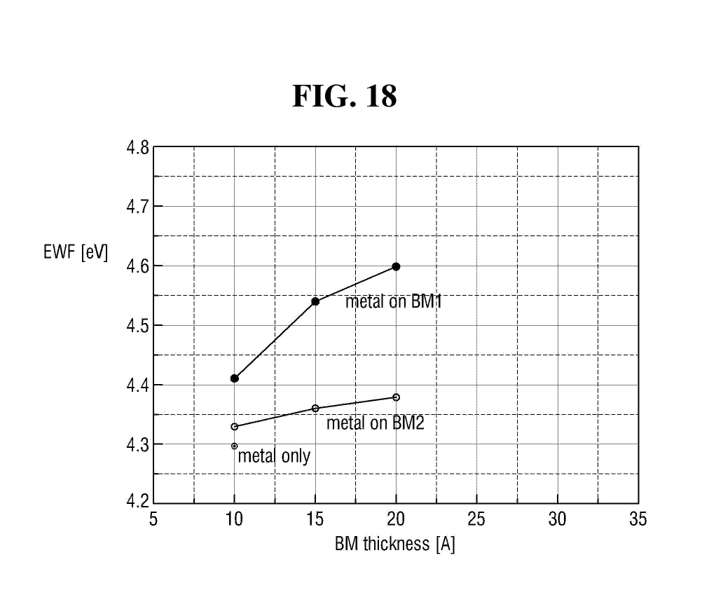

A 100 Å thick gate metal including metal (M)-aluminum (Al)-carbide is prepared. Work functions of the gate metal without a lower barrier metal, the gate metal with a lower barrier metal (BM1) including metal (Q)-nitride, and the gate metal with a lower barrier metal (BM2) including metal (M)-nitride, are measured. Changes in the work function of the gate metal are measured while varying thicknesses of lower barrier metals BM1 and BM2. The measurement result is illustrated in FIG. 18. Referring to FIG. 18, it may be understood that when the gate metal has lower barrier metals BM1 and BM2 formed thereunder, a work function of the gate metal may be greater than when the gate metal has no barrier metals BM1 and BM2. This is presumably because the barrier metals BM1 and BM2 serve to prevent a metallic material of the gate metal from being diffused.

It may also be understood that the work function of the gate metal is caused by changing materials forming the lower barrier metals BM1 and BM2, and that the work function of the gate metal is increased as the thicknesses of the lower barrier metals BM1 and BM2 increase. This is presumably because functions of the lower barrier metals BM1 and BM2 as barriers (for example, a function of preventing diffusion of a metallic material) may vary according to changes in composition materials and/or thicknesses of the lower barrier metals BM1 and BM2.

While example embodiments have been particularly shown and described, it will be understood by one of ordinary skill in the art that variations in form and detail may be made therein without departing from the spirit and scope of the claims.

What is claimed is:

1. A semiconductor device, comprising:
first and second fin active regions;
a gate insulation layer on the first and second fin active regions;
a first gate metal contacting the gate insulation layer on the first fin active region; and
a second gate metal on the first gate metal on the first fin active region and contacting the gate insulation layer on the second fin active region.

2. The semiconductor device of claim 1, wherein the first gate metal and the second gate metal include different materials.

3. The semiconductor device of claim 2, wherein a material included in the first gate metal and a material included in the second gate metal each include
at least one of a first metal-carbide, a first metal-second metal-carbide, a first metal-second metal, a first metal-second metal-nitride, a first metal-nitride, a first metal-silicide, and a first metal-silicon-nitride, and
a material different from the at least one material.

4. The semiconductor device of claim 3, wherein the second metal is aluminum.

5. The semiconductor device of claim 1, wherein
the first and second gate metals include a same material, and
the material is at least one of a first metal-carbide, a first metal-second metal-carbide, a first metal-second metal, a first metal-second metal-nitride, a first metal-nitride, a first metal-silicide, and a first metal-silicon-nitride.

6. The semiconductor device of claim 5, wherein a compositions ratio of the material in the first gate metal is different from a composition ratio of the material in the second gate metal.

7. The semiconductor device of claim 1, wherein a thickness of the second gate metal on the first fin active region and a thickness of the second gate metal on the second fin active region are a same thickness.

8. The semiconductor device of claim 1, wherein a thickness of the second gate metal on the first fin active region and a thickness of the second gate metal on the second fin active region are different.

9. The semiconductor device of claim 1, wherein work functions of the first and second gate metals on the first fin active region are different from a work function of the second gate metal on the second fin active region.

10. A semiconductor device, comprising:
first and second fin active regions protruding in a first direction perpendicular to a substrate and integral with the substrate, the first and second fin active regions extending in a second direction perpendicular to the first direction;
a gate insulation layer on the first and second fin active regions; and
first and second gate metals on the gate insulation layer and crossing the first and second fin active regions, the first and second gate metals extending in a third direction perpendicular to the first and second directions, the first and second gate metals sequentially stacked on the first fin active region, sidewalls of the first and second gate metals being aligned in the third direction, the second gate metal being in contact with the gate insulation layer on the second fin active region.

11. The semiconductor device of claim 10, wherein
the first fin active region includes a first source region and a first drain region in opposite sides of the first fin active region,
the second fin active region includes a second source region and a second drain region in opposite sides of the second fin active region,
the first fin active region, the first and second gate metals, the first source region and the first drain region, are part of a first transistor,
the second fin active region, the second gate metal, the second source region and the second drain region, are part of a second transistor, and
threshold voltages of the first and second transistors are different.

12. The semiconductor device of claim 11, wherein a difference between the threshold voltages of the first transistor and the second transistor is about 200 to 300 mV.

13. The semiconductor device of claim 10, wherein sidewalls of the gate insulation layer are aligned with the sidewalls of at least one of the first gate metal and the second gate metal in the third direction.

14. The semiconductor device of claim 10, further comprising:
a first insulation layer contacting the first and second fin active regions; and
a second insulation layer contacting the second gate metal, the second insulation layer being separate from the first insulation layer.

15. A semiconductor device, comprising:
a first fin field effect transistor (FIN-FET) with a first gate stack including first and second metal layers; and
a second FIN-FET with a second gate stack including the second metal layer, the second gate stack not including the first metal layer.

16. The semiconductor device of claim 15, wherein a work function of the second gate stack is different from a work function of the first gate stack.

17. The semiconductor device of claim 15, wherein the first and second FIN-FETs are part of a substrate.

18. The semiconductor device of claim 16, wherein
a threshold voltage difference exists between a threshold voltage of the first FIN-FET and a threshold voltage of the second FIN-FET, and
the threshold voltage difference is based on one of a difference in materials, composition ratios and thicknesses of the first and second gate stacks.

19. The semiconductor device of claim 18, wherein a thickness of the second metal layer in the first FIN-FET is different from a thickness of the second metal layer in the second FIN-FET.

20. The semiconductor device of claim 18, wherein the first and second FIN-FETs are both of a same conductivity type.
